(19) United States
(12) Patent Application Publication
(10) Pub. No.: US 2010/0236825 A1
(43) Pub. Date: Sep. 23, 2010

(54) Assemble structure of connection device and electric device, connection device and electric device used for the same

(75) Inventors: Hideharu Nagatomo, Kariya-city (JP); Tsutomu Suzuki, Hazu-gun (JP); Hironari Tajimi, Obu-city (JP); Takehiro Kanou, Yokkaichi-city (JP); Yusuke Okuhira, Yokkaichi-city (JP)

Correspondence Address: HARNESS, DICKEY & PIERCE, P.L.C., P.O. BOX 828, BLOOMFIELD HILLS, MI, 48303, US

(73) Assignees: DENSO CORPORATION, Kariya-city (JP); Anden Co., Ltd., Anjo-city (JP); Sumitomo Wiring Systems, Ltd., Yokkaichi-city (JP)

(21) Appl. No.: 12/661,446

(22) Filed: Mar. 17, 2010

(30) Foreign Application Priority Data
Mar. 23, 2009 (JP) 2009-070522

(51) Int. Cl. H05K 5/00

(52) U.S. Cl. 174/520

(57) ABSTRACT

An assemble structure includes: a connection device including a support element on one side of an attachment surface, a first connector on the attachment surface, and a key groove on a support surface of the support element; and the electric device including a casing to be attached to the attachment surface, a second connector on one surface of the casing electrically coupled with the first connector, and a key protruding from the one side of the casing. The electric device is rotatable via a hinge provided by the support element and the casing when one side of the casing faces a support surface of the support element. The key groove on the support surface corresponds to the key on the one side of the casing.

### CROSS REFERENCE TO RELATED APPLICATION

This application is based on Japanese Patent Application No. 2009-70522 filed on Mar. 23, 2009, the disclosure of which is incorporated herein by reference.

### FIELD OF THE INVENTION

The present invention relates to an assemble structure of a connection device and an electric device, a connection device and an electric device used for an assemble structure.

### BACKGROUND OF THE INVENTION

JP-A-2008-172889 teaches an assemble structure of a junction box (electric junction box, JB) and an electric controller as an electric control unit (ECU). In the assemble structure, the ECU having a square shape is fixed to an attachment surface of a body of the JB. The JB has the attachment surface, which corresponds to the ECU. Specifically, the ECU includes an axial portion with hooks, which are disposed on both ends of one side of the ECU. The JB includes a bearing portion on the attachment surface of the JB. The axial portion of the ECU is slid on the attachment surface so that the axial portion is inserted into the bearing portion. Then, the ECU is rotated around the axial portion so that the bottom of the ECU contacts the attachment surface and contacts electrically through the connectors. Thus, the ECU is assembled on the body of the JB.

The JB is mounted on a vehicle such that the body of the JB is in parallel to a driving direction of the vehicle. Alternatively, the body of the JB is perpendicular to the driving direction. Thus, there are various structures of the JB corresponding to a mounting structure on the vehicle. Further, there are various ECUs according to a type of the vehicle and a grade of the vehicle. Specifically, the number of elements mounted on the ECU and control functions of the ECU are various.

However, it is difficult to distinguish a certain type of the ECU only from appearance of the ECU since an element such as a case of the ECU is commonly manufactured among various ECUs. Thus, it is difficult to select a combination of the ECU and the JB at first view. Accordingly, the ECU may be assembled on a different type of the JB, so that a wrong combination is selected. In this case, the ECU does not function correctly.

### SUMMARY OF THE INVENTION

In view of the above-described problem, it is an object of the present disclosure to provide an assemble structure of a connection device and an electric device without assembling a wrong combination. It is another object of the present disclosure to provide a connection device used for an assemble structure, and it is further another object of the present disclosure to provide an electric device used for the assemble structure.

According to a first aspect of the present disclosure, an assemble structure of a connection device and an electric device includes: the connection device having an attachment surface and including a support element and a first connector, wherein the support element is disposed on one side of the attachment surface, and the support element protrudes from the attachment surface in a vertical direction of the attachment surface, and wherein the first connector is disposed on the attachment surface; and the electric device including a casing to be attached to the attachment surface and a second connector disposed on one surface of the casing, wherein the one surface of the casing faces the attachment surface, and the first connector is electrically coupled with the second connector. The electric device is rotatable via a hinge, which is provided by the support element and the casing, when one side of the casing faces a support surface of the support element. The electric device further includes a key, which protrudes from the one side of the casing in a vertical direction of the one side. The connection device further includes a key groove, which is disposed on the support surface of the support element in such a manner that a part of the support surface is concaved in the vertical direction of the support surface. The key groove on the support surface corresponds to the key on the one side of the casing.

In the above structure, when the combination of the connection device and the electric device is proper, the key corresponds to the key groove so that the electric device is assembled in the connection device. Thus, a wrong combination of the connection device and the electric device is not selected, so that the electric device does not function incorrectly.

Alternatively, the key may be spaced apart from the one surface of the casing. Alternatively, the casing may include an upper casing and a lower casing. The lower casing faces the attachment surface, and the upper casing is opposite to the attachment surface, and the key is disposed on the upper casing. Alternatively, the electric device may further include an axial portion, which is disposed on the one side of the casing. The support element further includes a bearing portion, which is disposed on the support surface, and the axial portion and the bearing portion provide the hinge when the axial portion is engaged with the bearing portion. Further, the connection device may further include a first lock element, which is disposed on the other side of the casing. The other side of the casing is opposite to the one side of the casing. The electric device may further include a second lock element, which is disposed on the other side of the attachment surface. The other side of the attachment surface is opposite to the one side of the attachment surface. The first lock element is engaged with the second lock element so that the electric device is fixed to the connection device. Furthermore, the casing may have a square shape with four sides, and the four sides of the casing include the one side of the casing and the other side of the casing. The attachment surface may have a square shape with four sides, and the four sides of the attachment surface include the one side of the attachment surface and the other side of the attachment surface. The support surface faces an inside of the attachment surface. Further, the connection device may further include an outer wall, which is disposed on three sides of the attachment surface other than the one side of the attachment surface. The outer wall and the support element surround the attachment surface, and the electric device is fixed to the connection device at a predetermined position, which is defined by the attachment surface, the outer wall and the support element.

According to a second aspect of the present disclosure, an assemble structure of a connection device and an electric device includes: the connection device having an attachment surface and including a support element and a first connector, wherein the support element is disposed on one side of the attachment surface, and the support element protrudes from the attachment surface in a vertical direction of the attachment surface, and wherein the first connector is disposed on the attachment surface; and the electric device including a casing to be attached to the attachment surface and a second connector disposed on one surface of the casing, wherein the one surface of the casing faces the attachment surface, and the first connector is electrically coupled with the second connector. The electric device is rotatable via a hinge, which is provided by the support element and the casing, when one side of the casing faces a support surface of the support element. The electric device further includes key groove, which is disposed on the one side of the casing in such a manner that a part of the one side of the casing is concaved in the vertical direction of the one side of the casing. The connection device further includes a key, which protrudes from the support surface of the support element in the vertical direction of the support surface. The key groove on the one side of the casing corresponds to the key on the support surface.

In the above structure, when the combination of the connection device and the electric device is proper, the key corresponds to the key groove so that the electric device is assembled in the connection device. Thus, a wrong combination of the connection device and the electric device is not selected, so that the electric device does not function incorrectly.

According to a third aspect of the present disclosure, an electric device to be attached to a connection device having an attachment surface and including a support element and a first connector, wherein the support element is disposed on one side of the attachment surface, and the support element protrudes from the attachment surface in a vertical direction of the attachment surface, and wherein the first connector is disposed on the attachment surface, the electric device includes: a casing to be attached to the attachment surface; a second connector disposed on one surface of the casing, wherein the one surface of the casing fasces the attachment surface, and the first connector is electrically coupled with the second connector; an axial portion disposed on one side of the casing; and a key disposed on the one side of the casing. The axial portion and the support element provide a hinge so that the electric device is rotatable around the hinge with respect to the connection device, and the key protrudes from the one side of the casing in the vertical direction of the one side.

In the above electric device, when the combination of the connection device and the electric device is proper, the key corresponds to the key groove so that the electric device is assembled in the connection device. Thus, a wrong combination of the connection device and the electric device is not selected, so that the electric device does not function incorrectly.

According to a fourth aspect of the present disclosure, a connection device to be attached to an electric device having a casing and a second connector, which is disposed on one surface of the casing, the connection device includes: an attachment surface, on which the electric device is to be arranged; a support element disposed on one side of the attachment surface, wherein the support element protrudes from the attachment surface in a vertical direction of the attachment surface; a first connector disposed on the attachment surface; and a key groove disposed on a support surface of the support element in such a manner that a part of the support surface is concaved in the vertical direction of the support surface. The first connector is to be electrically coupled with the second connector.

In the above connection device, when the combination of the connection device and the electric device is proper, the key corresponds to the key groove so that the electric device is assembled in the connection device. Thus, a wrong combination of the connection device and the electric device is not selected, so that the electric device does not function incorrectly.

### BRIEF DESCRIPTION OF THE DRAWINGS

The above and other objects, features and advantages of the present invention will become more apparent from the following detailed description made with reference to the accompanying drawings. In the drawings:

FIG. 1 is a diagram showing an assemble structure of a junction box and an electric controller according to a first embodiment;

FIGS. 2 and 3 are diagrams showing the assemble structure in an assembling step of the junction box and the electric controller;

FIG. 4 is a diagram showing a cross sectional view of the assemble structure in the assembling step of the junction box and the electric controller;

FIG. 5 is a diagram showing a cross sectional view of the assemble structure of the junction box and the electric controller after the assembling step; and

FIG. 6 is a diagram showing a cross sectional view of a key in the assembling step.

### DETAILED DESCRIPTION OF THE PREFERRED EMBODIMENTS

### First Embodiment

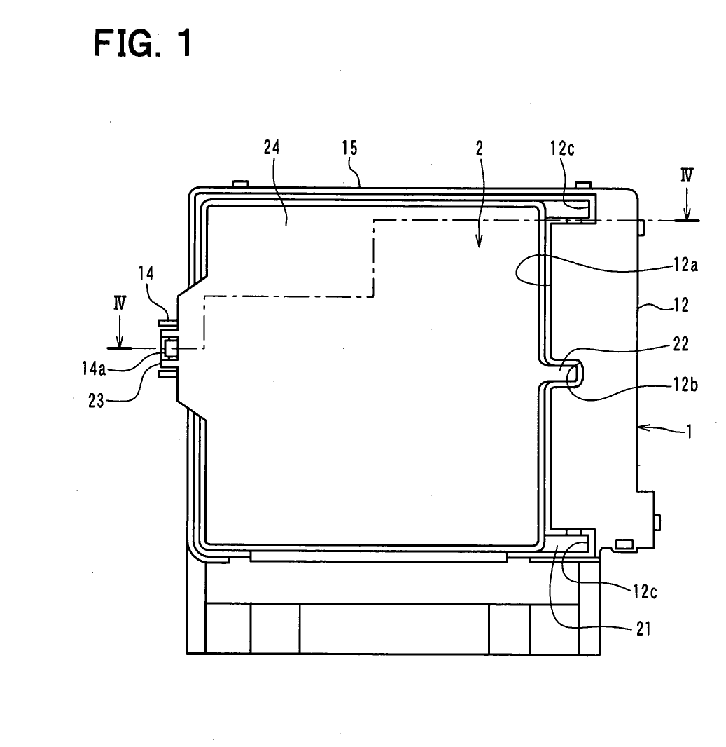

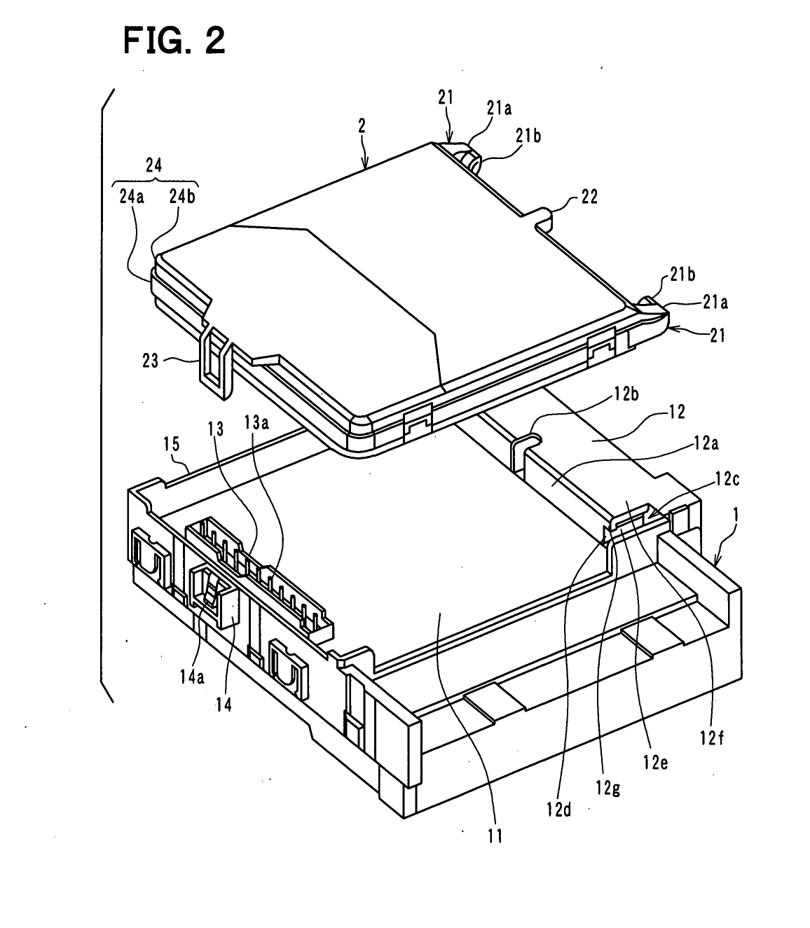

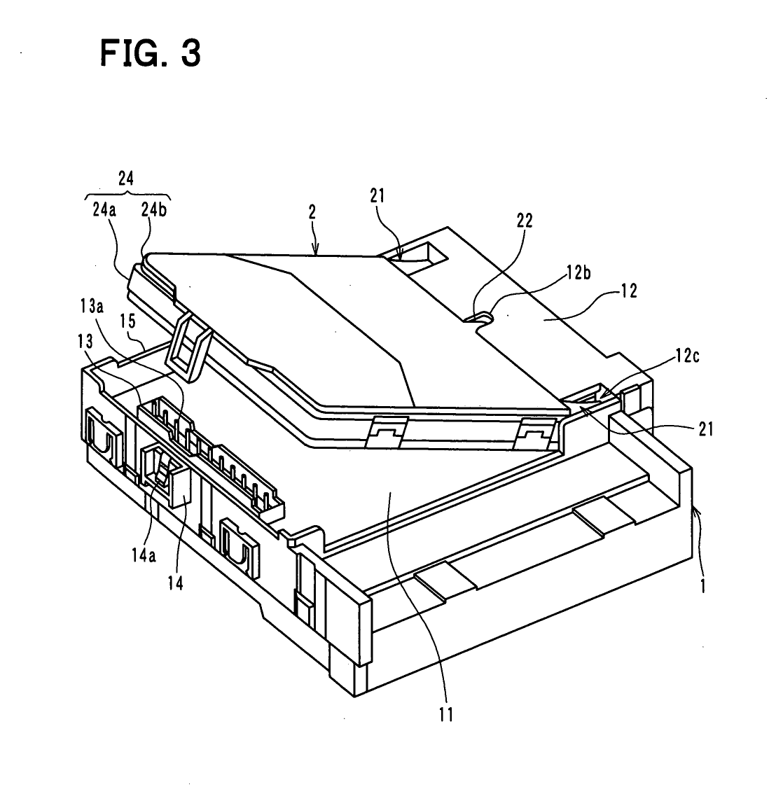

An assemble structure of a junction box 1 as JB, i.e., connection device and an electric controller 2 as ECU, i.e., electric device for a vehicle. The assemble structure is suitably used for an in-vehicle device. FIG. 1 shows the assemble structure of the junction box 1 and the electric controller 2. FIGS. 2 and 3 show the assemble structure in an assembling step of the junction box 1 and the electric controller 2. The assemble structure of the junction box 1 and the electric controller 2 will be explained.

The JB 1 has an upper view of a square shape, as shown in FIG. 1. The JB 1 includes a wiring structure therein, which is electrically coupled with the ECU 2. When the JB 1 is assembled into the ECU 2, the wiring structure of the JB 1 is electrically coupled with the ECU 2. Accordingly, the ECU 2 is coupled with an electric wire for various devices on the vehicle via a connector (not shown) of the JB 1. The connector of the JB 1 is used for coupling with an external device.

JB 1 includes an attachment surface 11, a support element 12, a connector 13 and a lock element 14, as shown in FIGS. 2 and 3.

The attachment surface 11 is disposed on one side of the JB 1, and has a shape corresponding to the ECU 2. Specifically, the attachment surface of the JB 1 is a flat square surface. The support element 12 and an outer wall 15 surround the attachment surface 11 so that four sides of the attachment surface 11 are surrounded with the support element 12 and an outer wall 15. When the ECU 2 is assembled into the JB 1 so as to contact the ECU 2 on the attachment surface 11, the ECU 2 is surrounded with the support element 12 and an outer wall 15 so that the ECU 2 is positioned at a certain place.

The support element 12 is disposed on one side of the attachment surface 11. The support element 12 includes a support surface 12a, which faces one side of the ECU 2 when the ECU 2 is assembled into the JB 1. The support element 12 further includes a key groove 12b as a concavity so that the support surface 12a is concaved. The position of the key groove 12b is a predetermined place spaced apart from each end of the support element 12. A distance between one end of the support element 12 and the key groove 12b may be equal to or different from a distance between the other end of the support element 12 and the key groove 12b. Thus, the position of the key groove 12b is determined based on a type of the ECU 2, which is to be assembled into the JB 1. The position of the key groove 12b corresponds to a key 22 of the ECU 2.

A bearing portion 12c is disposed on each end of the support element 12. The bearing portion 12c has a slit shape with a notch so that the support surface 12a is notched in a vertical direction of the JB1. Specifically, the bearing portion 12c includes an insertion slot 12d, an accommodation portion 12e, an upper wall 12f and a protrusion wall 12g. The insertion slot 12d is an entry place, in which a top of an axial portion 21 of the ECU 2 is inserted. The insertion slot 12d is formed on the support surface 12a of the support element 12. The accommodation portion 12e accommodates the top of the axial portion 21, which is inserted into the insertion slot 12d. The upper wall 12f protrudes into the accommodation portion 12e in parallel to the attachment surface 11. The upper wall 12f prevents the top of the axial portion 21 accommodated in the accommodation portion 12e from dropping off from the bearing portion 12c. The protrusion wall 12g protrudes from the upper wall 12f in the vertical direction of the attachment surface 11. The protrusion wall 12g prevents the top of the axial portion 21 accommodated in the accommodation portion 12e from dropping off from the portion 12e toward one side of the outer wall 15, which faces the support surface 12a.

The connector 13 electrically connects to a certain portion of the ECU 2 so that a wiring of the JB 1 is electrically coupled with the ECU 2. The connector 13 protrudes from the attachment surface 11 in the vertical direction of the surface 11. The connector 13 includes multiple pins 13a, each of which protrudes from the attachment surface 11 in the vertical direction of the surface 11. Multiple pins 13a of the JB 1 are connected to a connector 25 of the ECU 2 when the ECU 2 is assembled into the JB 1.

The lock element 14 is disposed on the one side of the outer wall 15, which faces the support surface 12a. Specifically, the lock element 14 is disposed on an outer side of the outer wall 15. The lock element 14 has a hook 14a for hooking a lock element 23 of the ECU 2 so that the lock element 14 prevents the ECU 2 from dropping off from the JB 1.

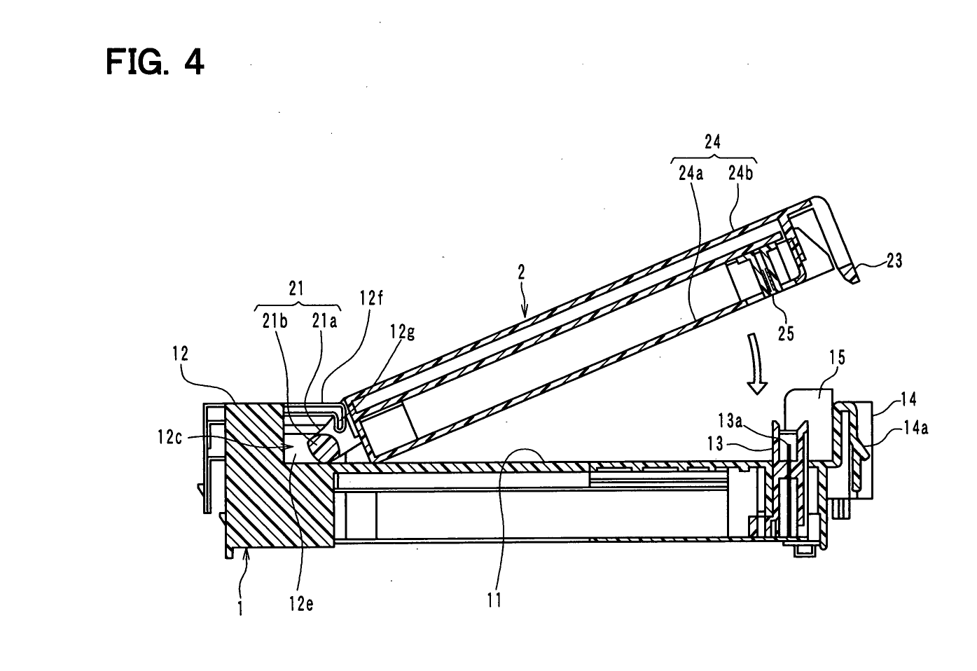

The ECU 2 has an upper view of a square shape. An electric device such as a micro computer is mounted on the ECU 2. The micro computer stores a program for executing a control function in accordance with a type of the vehicle and a grade of the vehicle. A connector 25 is disposed on a lower surface of the ECU 2, which faces the attachment surface 11, as shown in FIG. 4. When the ECU 2 is assembled on the attachment surface 11 of the JB 1, the connector 25 disposed on the lower surface of the ECU 2 is engaged with the connector 13 of the JB 1 so that the ECU 2 is electrically coupled with the JB 1. The ECU 2 further includes the axial portion 21, a key 22 and the lock portion 23.

The axial portion 21 is disposed on one side of the ECU 2, which faces the support element 12. The axial portion 21 is engaged with the bearing portion 12c so that the ECU 2 is supported on the JB 1. Further, the ECU 2 is rotated around the axial portion 21, which is supported by the bearing portion 12c. Thus, the ECU 2 is assembled into the JB 1. The axial portion 21 and the bearing portion 12c provide a hinge. Specifically, the axial portion 21 includes a support body 21a and a hook portion 21b. The support body 21a protrudes from the one side of the ECU 2 in the vertical direction. The hook portion 21b protrudes from the support body 21a on one end of the one side of the ECU 2 toward another hook portion 21b on the other end of the one side of the ECU 2. The hook portion 21b is accommodated in the accommodation portion 12e of the bearing portion 12c, so that the axial portion 21 is prevented from dropping off from the bearing portion 12c.

The key 22 is disposed on the one side of the ECU 2, which faces the support element 12. Specifically, the key 22 has a square shaped protrusion, which protrudes from the one side of the ECU 2 vertically. The position of the key 22 corresponds to the position of the key groove 12b of the JB 1. The position of the key 22 is spaced apart from the one end of the one side of the ECU 2, and spaced apart from the other end of the one side of the ECU 2. The outer shape of the ECU 2 is covered with a casing 24. The casing 24 includes a lower casing 24a and an upper casing 24b. The lower casing 24a faces the attachment surface 11 of the JB 1. The upper casing 24b is opposite to the attachment surface. 11. The key 22 is formed on the upper casing 24b.

The lock element 23 of the ECU 2 and the lock element 14 of the JB 1 provide a lock mechanism. The lock element 23 is hooked by the hook 14a of the lock element 14 so that the ECU 2 is restricted from separating from the JB 1 in the vertical direction of the attachment surface 11. Specifically, the lock element 23 protrudes from the other side of the ECU 2, which is opposite to the one side of the ECU 2 on which the key 22 is formed. The lock element 23 turns down vertically so that the lock element 23 is perpendicular to the surface of the ECU 2. This bent portion of the lock element 23 turning down vertically has a U shape. A top of the U shape of the lock element 23 is engaged with the hook 14a so that the ECU 2 is restricted from sliding and moving from the JB 1.

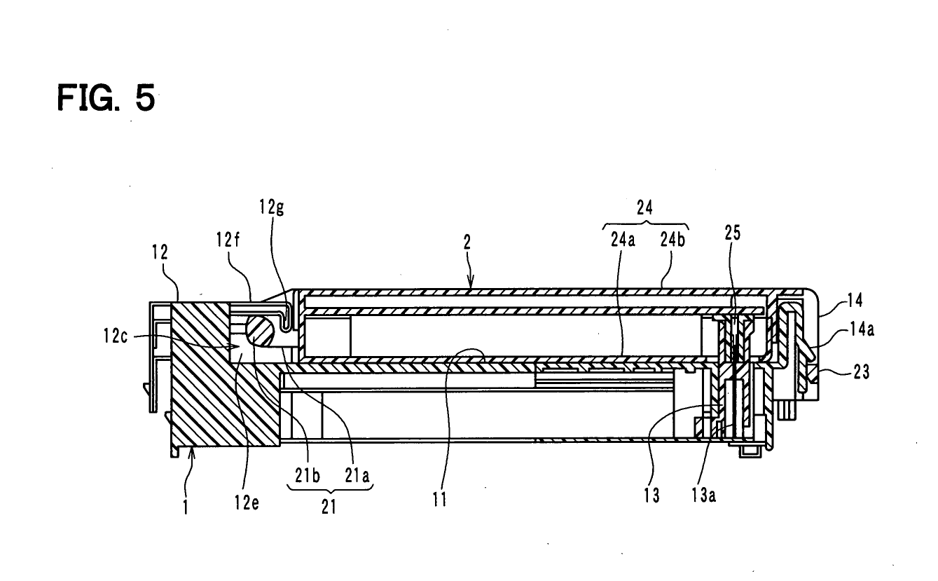

Thus, the assemble structure of the ECU 2 and the JB 1 is described. Next, an assembling method will be explained. FIG. 4 shows a cross section of the assemble structure during a step of assembling the ECU 2 and the JB 1. FIG. 5 shows a cross section of the assemble structure after the step of assembling the ECU 2 and the JB 1. FIGS. 4 and 5 are cross sectional views showing the assemble structure of the ECU 2 and the JB 1 taken along line IV-IV in FIG. 1.

Firstly, the ECU 2 is arranged over the attachment surface 11 of the JB 1, as shown in FIG. 2. Then, the ECU 2 is tilted such that the top of the axial portion 21 faces the attachment surface 11. Then, as shown in FIG. 3, the top of the axial portion 21 is slid on the attachment surface 11, so that the top of the axial portion 21 is engaged in the accommodation portion 12e through the insertion slot 12d. At this time, when the ECU 2 is engaged with the JB 1, the key 22 corresponds with the key groove 12b since the ECU 2 corresponds to the JB 1. Thus, the key 22 is engaged in the key groove 12b. Accordingly, the key 22 does not prevent the ECU from being engaged with the JB 1. The axial portion 21 is completely inserted in the insertion slot 12d.

Then, when the surface of the ECU 2, which is disposed on the one side of the ECU 2 on which the axial portion 21 is arranged, contacts the support surface 12a of the support element 12, the ECU 2 is rotated along with an arrow direction in FIG. 4 under a condition that the axial portion 21 is engaged with the bearing portion 12c. At this time, since the axial portion 21 includes the hook portion 21b, and the support element 12 includes at least of the upper wall 12f and the protrusion 12g, the hook portion 21b, the hook portion 21b is hooked to the upper wall 12f or the protrusion wall 12g so that the axial portion 21 of the ECU 2 is restricted from being dropped off from the bearing portion 12c of the JB 1.

When the ECU 2 is rotated, the connector 25 of the ECU 2 is coupled with the connector 13 of the JB 1. Further, the lock element 23 of the ECU 2 is elastically deformed along with a slanting surface of the hook 14a. Further, the ECU 2 is rotated, and therefore, the connector 25 of the ECU 2 is completely connected to the connector 13 of the JB 1. In this case, the lock element 23, which is elastically deformed, turns back. Thus, the U shape of the lock element 23 is engaged with the hook 14a. Thus, the ECU 2 is assembled into the JB 1 completely.

In the assemble structure of the ECU 2 and the JB 1, the key groove 12b is formed in the JB 1, and the key 22 is formed in the ECU 2. When the combination of the JB 1 and the ECU 2 is proper, the key 22 corresponds to the key groove 12b, and the ECU 2 is assembled into the JB 1. When the combination of the JB 1 and the ECU 2 is not proper, the key 22 does not correspond to the key groove 12b, and the key 22 cannot be engaged in the key groove 12b. Accordingly, even if it is difficult to distinguish a certain type of the ECU only from appearance of the ECU, the ECU 2 cannot be assembled in the JB 1 when the combination of the JB 1 and the ECU 2 is not proper. Thus, the ECU 2 is not assembled in a wrong JB 1, and a wrong combination of the ECU 2 and the JB 1 is not selected.

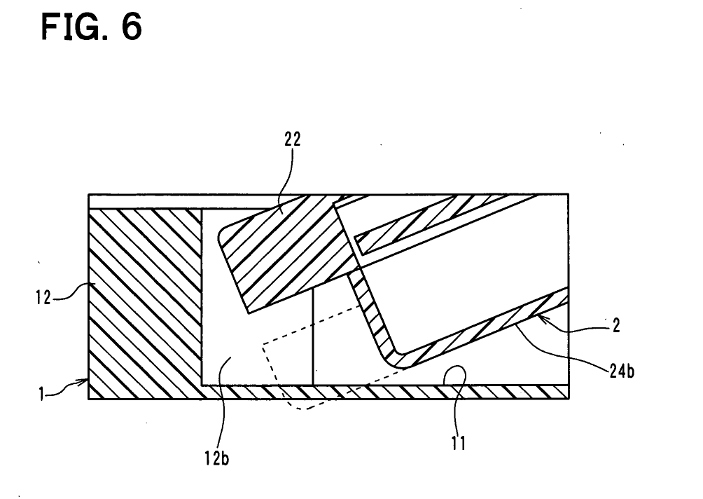

The key 22 is formed in the upper casing 24b, not in the lower casing 24a so that the key 22 is spaced apart from one surface of the ECU 2 facing the attachment surface 11 of the JB 1. Thus, the following advantages are obtained. These advantages will be explained with reference to FIG. 6.

FIG. 6 shows a combination of the JB 1 and ECU 2 when the ECU 2 is assembled in the JB 1. Specifically, FIG. 6 shows a cross sectional view of the ECU 2 and the JB 1 taken along line passing through the key 22. As described with a broken line, if the key 22 is formed in the lower casing 24a so that one side of the key 22 is on the same plane as the one surface of the ECU 2, which faces the attachment surface 11 of the JB 1, the key 22 contacts the attachment surface 11 so that the key 22 blocks from being inserted into the key groove 12b. Thus, when the key 22 is formed in the upper casing 24b so that the key 22 is spaced apart from the one side of the ECU 2, which faces the attachment surface 11, the key 22 does not block the key 22 from being inserted into the key groove 12b. In this case, the key 22 does not contact the attachment surface 11. Even if the key 22 is formed in the lower casing 24a, as long as the key 22 is spaced apart from the one side of the ECU 2, which faces the attachment surface 11, the key 22 does not block the key 22 from being inserted into the key groove 12b.

### Other Embodiments

In the above embodiment, the bearing portion 12c of the JB 1 is arranged to face the axial portion 21 of the ECU 2so that the support surface 12a faces the one side of the ECU 2, and the ECU 2 is rotated around the axial portion 21 as a rotation axis with using the bearing portion 12c so that the ECU 2 is assembled inn the JB 1. Further, the key 22 is disposed on the one side of the ECU 2 facing the support surface 12a, and the key groove 12b is formed on the support surface 12a of the JB 1, so that a key mechanism is provided.

In the above embodiment, the key groove 12b of the JB 1 is a square shaped concavity, and the key 22 of the ECU 2 is a square shaped protrusion. Alternatively, for example, an upper view of each of the key 22 and the key groove 12b may be a triangle shape, a half circle shape, or a trapezoid shape.

In the above embodiment, the JB 1 includes the key groove 12b, and the ECU 2 includes the key 22. Alternatively, the JB 1 may include a key, and the ECU 2 may include a key groove. In this case, a part of the casing 24 of the ECU 2 is concaved, so that an accommodation space in the ECU 2 is reduced. Thus, preferably, the JB 1 includes the key groove 12b, and the ECU 2 includes the key 22.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. An assemble structure of a connection device and an electric device comprising:
the connection device having an attachment surface and including a support element and a first connector, wherein the support element is disposed on one side of the attachment surface, and the support element protrudes from the attachment surface in a vertical direction of the attachment surface, and wherein the first connector is disposed on the attachment surface; and
the electric device including a casing to be attached to the attachment surface and a second connector disposed on one surface of the casing, wherein the one surface of the casing faces the attachment surface, and the first connector is electrically coupled with the second connector,
wherein the electric device is rotatable via a hinge, which is provided on the support element and the casing, when one side of the casing faces a support surface of the support element,
wherein the electric device further includes a key, which protrudes from the one side of the casing in a vertical direction of the one side,
wherein the connection device further includes a key groove, which is disposed on the support surface of the support element in such a manner that a part of the support surface is concaved in the vertical direction of the support surface, and
wherein the key groove on the support surface corresponds to the key on the one side of the casing.

2. The assemble structure according to claim 1,
wherein the key is spaced apart from the one surface of the casing.

3. The assemble structure according to claim 1,
wherein the casing includes an upper casing and a lower casing,
wherein the lower casing faces the attachment surface, and the upper casing is opposite to the attachment surface, and
wherein the key is disposed on, the upper casing.

4. The assemble structure according to claim 1,
wherein the electric device further includes an axial portion, which is disposed on the one side of the casing,
wherein the support element further includes a bearing portion, which is disposed on the support surface, and
wherein the axial portion and the bearing portion provide the hinge when the axial portion is engaged with the bearing portion.

5. The assemble structure according to claim 4,
wherein the electric device further includes a first lock element, which is disposed on other side of the casing,
wherein the other side of the casing is opposite to the one side of the casing,
wherein the connection device further includes a second lock element, which is disposed on other side of the attachment surface,
wherein the other side of the attachment surface is opposite to the one side of the attachment surface, and
wherein the first lock element is engaged with the second lock element so that the electric device is fixed to the connection device.

6. The assemble structure according to claim 5,
wherein the casing has a square shape with four sides,
wherein the four sides of the casing include the one side of the casing and the other side of the casing,
wherein the attachment surface has a square shape with four sides,
wherein the four sides of the attachment surface include the one side of the attachment surface and the other side of the attachment surface, and
wherein the support surface faces an inside of the attachment surface.

7. The assemble structure according to claim 6,
wherein the connection device further includes an outer wall, which is disposed on three sides of the attachment surface other than the one side of the attachment surface,
wherein the outer wall and the support element surround the attachment surface, and
wherein the electric device is fixed to the connection device at a predetermined position, which is defined by the attachment surface, the outer wall and the support element.

8. An assemble structure of a connection device and an electric device comprising:
the connection device having an attachment surface and including a support element and a first connector, wherein the support element is disposed on one side of the attachment surface, and the support element protrudes from the attachment surface in a vertical direction of the attachment surface, and wherein the first connector is disposed on the attachment surface; and
the electric device including a casing to be attached to the attachment surface and a second connector disposed on one surface of the casing, wherein the one surface of the casing faces the attachment surface, and the first connector is electrically coupled with the second connector,
wherein the electric device is rotatable via a hinge, which is provided on the support element and the casing, when one side of the casing faces a support surface of the support element,
wherein the electric device further includes key groove, which is disposed on the one side of the casing in such a manner that a part of the one side of the casing is concaved in the vertical direction of the one side of the casing,
wherein the connection device further includes a key, which protrudes from the support surface of the support element in the vertical direction of the support surface, and
wherein the key groove on the one side of the casing corresponds to the key on the support surface.

9. The assemble structure according to claim 8,
wherein the electric device further includes an axial portion, which is disposed on the one side of the casing,
wherein the support element further includes a bearing portion, which is disposed on the support surface, and
wherein the axial portion and the bearing portion provide the hinge when the axial portion is engaged with the bearing portion.

10. The assemble structure according to claim 9,
wherein the electric device further includes a first lock element, which is disposed on other side of the casing,
wherein the other side of the casing is opposite to the one side of the casing,
wherein the connection device further includes a second lock element, which is disposed on other side of the attachment surface,
wherein the other side of the attachment surface is opposite to the one side of the attachment surface, and
wherein the first lock element is engaged with the second lock element so that the electric device is fixed to the connection device.

11. The assemble structure according to claim 10,
wherein the casing has a square shape with four sides,
wherein the four sides of the casing includes the one side of the casing and the other side of the casing,
wherein the attachment surface has a square shape with four sides,
wherein the four sides of the attachment surface includes the one side of the attachment surface and the other side of the attachment surface, and
wherein the support surface faces an inside of the attachment surface.

12. The assemble structure according to claim 11,
wherein the connection device further includes an outer wall, which is disposed on three sides of the attachment surface other than the one side of the attachment surface,
wherein the outer wall and the support element surround the attachment surface, and
wherein the electric device is fixed to the connection device at a predetermined position, which is defined by the attachment surface, the outer wall and the support element.

13. An electric device to be attached to a connection device having an attachment surface and including a support element and a first connector, wherein the support element is disposed on one side of the attachment surface, and the support element protrudes from the attachment surface in a vertical direction of the attachment surface, and wherein the first connector is disposed on the attachment surface, the electric device comprising:
a casing to be attached to the attachment surface;
a second connector disposed on one surface of the casing, wherein the one surface of the casing faces the attachment surface, and the first connector is electrically coupled with the second connector;
an axial portion disposed on one side of the casing; and
a key disposed on the one side of the casing,
wherein the axial portion and the support element provide a hinge so that the electric device is rotatable around the hinge with respect to the connection device, and
wherein the key protrudes from the one side of the casing in the vertical direction of the one side.

14. A connection device to be attached to an electric device having a casing and a second connector, which is disposed on one surface of the casing, the connection device comprising:
an attachment surface, on which the electric device is to be arranged;
a support element disposed on one side of the attachment surface, wherein the support element protrudes from the attachment surface in a vertical direction of the attachment surface;
a first connector disposed on the attachment surface; and
a key groove disposed on a support surface of the support element in such a manner that a part of the support surface is concaved in the vertical direction of the support surface,
wherein the first connector is to be electrically coupled with the second connector.
